(19) United States
(12) Patent Application Publication
(10) Pub. No.: US 2006/0132187 A1
(43) Pub. Date: Jun. 22, 2006

(54) Body biasing for dynamic circuit

(76) Inventors: James W. Tschanz, Portland, OR (US); Ram K. Krishnamurthy, Portland, OR (US); Siva G. Narendra, Portland, OR (US); Vivek K. De, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/018,011

(22) Filed: Dec. 20, 2004

(51) Int. Cl. H03K 19/096

(52) U.S. Cl. 326/95

(57) ABSTRACT

In some embodiments, a circuit is provided that comprises a dynamic circuit and a body bias circuit. The dynamic circuit has a keeper transistor. The body bias circuit is coupled to the keeper transistor and is configured to body bias the keeper transistor in accordance with a leakage associated with the dynamic circuit. Other embodiments are disclosed herein.

### TECHNICAL FIELD

Embodiments disclosed herein relate generally to integrated circuit (“IC”) devices and in particular to transistor body biasing circuits and schemes.

### BACKGROUND

With high performance capabilities, dynamic logic circuits are used in integrated circuit (“IC”) chips such as microprocessor chips. (As used herein, the term “chip” (or die) refers to a piece of a material, such as a semiconductor material, that includes a circuit such as an integrated circuit or a part of an integrated circuit.) Unfortunately, their performance can be impaired as a result of leaky transistors, especially as transistor dimensions get smaller. One approach to solving this problem is to use “keeper” transistors to supply at least part of the charge lost as a result of leakage.

FIG. 1 shows a prior art example of a dynamic logic circuit 101 employing a keeper transistor M_{K}. Dynamic circuit 101 generally comprises a logic circuit 103, a precharge transistor Mₚ, a keeper transistor M_{K}, and an inverter Ul. The logic circuit 103 includes NMOS transistors (M₀ to M₅) with inputs at A_{O} to A₅ and an output at the dynamic output node (D). (In the depicted logic circuit, D=[A₀A₁+A₂A₃+A₄A₅]′.) The precharge transistor Mₚ and keeper transistor Mₖ (which in the depicted figure are PMOS transistors) are coupled between V_{cc} and the dynamic node (D), and the inverter U1 is coupled between the dynamic node (D) and the gate input of the keeper transistor M_{K}. (Dynamic logic circuits may also include a “footer” NMOS transistor controlled by the clock which turns off the pulldown stack during the precharge phase.)

In operation, during a “precharge” state (when the CLK signal is Low in this circuit), the precharge transistor Mₚ charges the dynamic output node to a logic High precharge voltage level. Subsequently, during an evaluate state (when the CLK signal goes High), the dynamic node (D) either discharges or remains sufficiently charged to “evaluate” Low or High, respectively, depending on the values of gate inputs A₀ to A₅. That is, if both A0 and A1 or A2 and A3 or A4 and A5 are High to turn on a transistor “stack” formed by M₀/M₁, M₂/M₃, or M₄/M₅, respectively, then the dynamic node (D) becomes coupled to ground and discharges thereby evaluating Low. Otherwise it stays charged and is (or at least should) evaluate High. The keeper transistor turns on during the precharge state as the dynamic node becomes sufficiently charged. If the dynamic node is suppose to evaluate High (based on the logic inputs), the keeper transistor stays on serving to help hold the charge during an evaluate state to prevent an errant “droop” that might otherwise occur as a result of leakage in the logic circuit transistors.

To function effectively, the keeper transistor M_{K} should sufficiently hold the dynamic node (D) even under the worst-case leakage conditions, which can deviate widely from expected leakage. For example, chips having circuits with wide domino structures (e.g., many dynamic gates cascaded together) can have worst-case leakage that is substantial and thus be especially vulnerable to dynamic node droop. To maintain reliability in these circuits, large keeper transistors are typically used. They are usually sized so that they can supply the expected worst-case leakage current, taking into account possible process variations in transistor fabrication. In reality, however, many of the fabricated chips do not have the worst-case leakage resulting in their keeper transistors being over-sized. Unfortunately, the use of over-sized keeper transistors degrades the performance of the gate by opposing discharge during a Low evaluation.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a schematic diagram of a prior art dynamic logic circuit.

FIG. 2 schematically shows a body bias circuit for body biasing keeper transistors in one or more dynamic logic circuits according to some embodiments of the present invention.

FIG. 3 is a block diagram of a system having a processor chip with body biased keeper transistors in accordance with some embodiments of the present invention.

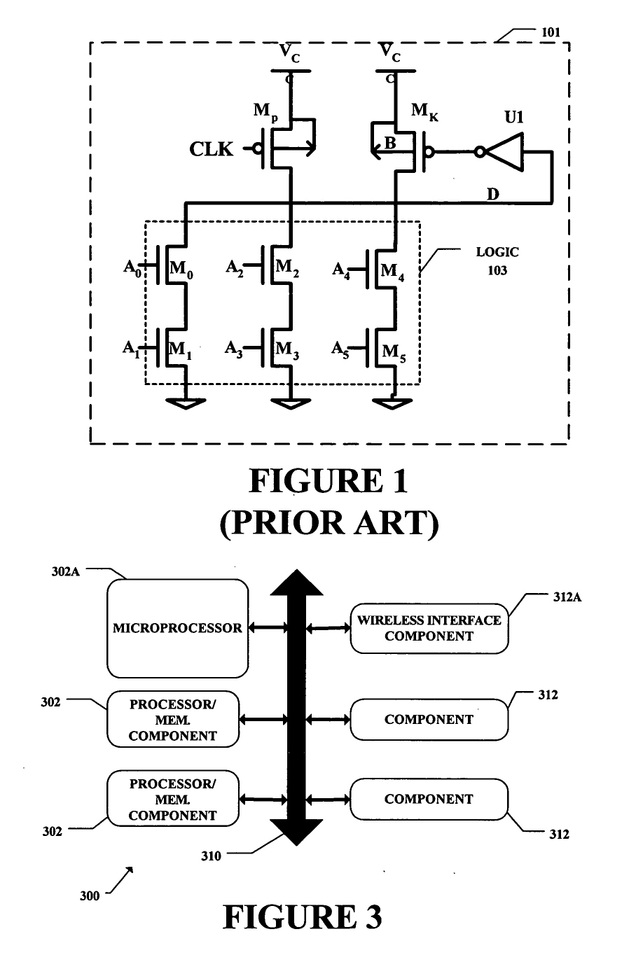

### DETAILED DESCRIPTION

In this disclosure, various approaches for providing suitably sized transistors (such as a keeper transistor) in a dynamic circuit are presented. In some embodiments, one or more keeper transistors in a chip are body biased so that their effective strengths can be made to correspond to leakage associated with the dynamic circuit or chip to which they belong.

Body biasing generally refers to applying a voltage bias between the body and source of an NMOS or PMOS transistor. (The terms “NMOS transistor” or “N-type MOSFET” refer to an N-type metal-oxide-semiconductor field-effect-transistor. Likewise, the term “PMOS transistor”or “P-type MOSFET” refer to a P-type metal-oxide-semiconductorf field-effect-transistor. Note that the principles set forth herein could apply to other transistors with biasing capabilities analogous to body biasing in MOSFET devices.) Body biasing such a transistor has the effect of adjusting its strength by adjusting the magnitude of its threshold voltage level (V_{T}). A forward body bias will generally lower the magnitude of a transistor's threshold voltage (|V_{T}|), while a reverse body bias will generally increase it. (Note that the terms: “threshold voltage” or “threshold voltage level” refer to the absolute value or magnitude, |V_{T}|, of a threshold voltage) An NMOS transistor is forward body biased when its body to source voltage (V_{BS}) is positive, while a PMOS transistor is forward body biased when its source to body voltage (V_{SB}) is positive. On the other hand, an NMOS device is reverse biased when its body to source voltage is biased at a negative level (V_{BS}<0), whereas a PMOS transistor is reverse biased when its source to body is at a negative level (V_{SB}<0).

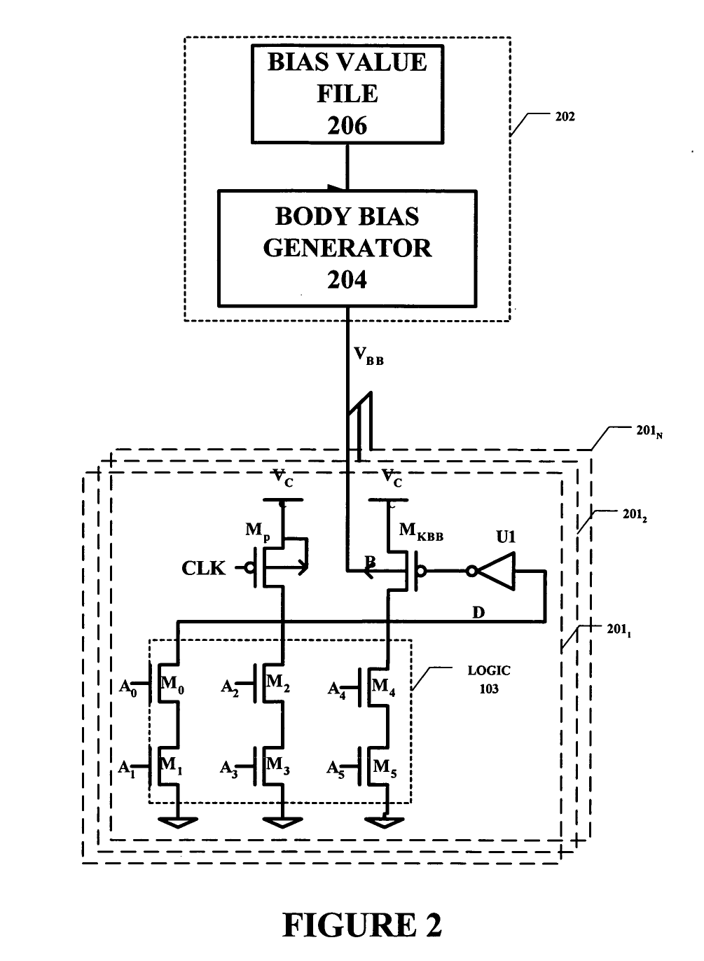

FIG. 2 schematically shows a body bias circuit 202 for body biasing keeper transistors M_{KBB} in one or more dynamic logic circuits 201₁ to 201_{N} according to some embodiments of the present invention. The body bias circuit 202 is coupled to a keeper transistor M_{KBB} in the dynamic logic circuits 201₁ to 201_{N}. Note that the dynamic logic circuit 201A is essentially the same as the prior art dynamic logic circuit 101 except that the keeper transistor M_{KBB} is configured with its body (e.g., N-type well) coupled to the body bias circuit 202 rather than to V_{cc} (or its source) thereby allowing a bias voltage to be applied between its body and it source.

As used herein, the terms “dynamic logic circuit” or “dynamic circuit” refer to any dynamic (or clocked) circuit or circuit portion such as a PE (pass-evaluate) gate circuit or NP (Zipper) gate circuit. A dynamic circuit could constitute (or be part of) a single gate or several gates cascaded together such as in a domino logic circuit. There may be several or numerous dynamic circuits in a chip. They may be similar, different, near one another, or spaced apart.

As used herein, a “keeper” transistor refers to any transistor in a dynamic circuit used to hold (or assist in holding) charge at a dynamic node for an evaluate (or similar) state. A keeper transistor could be an NMOS or a PMOS transistor. In addition, it could be one of several transistors used to provide charge to a dynamic node for a High evaluation. For example, in some designs, a keeper stack may be implemented with a turned on transistor connected to the dynamic node through a second keeper transistor that turns on (and stays on) when the dynamic node is to evaluate High. In other cases, as with M_{KBB} in FIG. 2, a single transistor may be used to perform “keeper” functionality. (It should be recognized that the terms “precharge” and “evaluate” are used in their broadest sense and should not be read to imply a particular type of logic such as PE logic. A precharge state occurs any time a clock, or equivalent, signal is at a level causing a dynamic node to charge. Likewise, an evaluate state occurs whenever data on a dynamic node, or downstream gate, is read or otherwise deemed to be valid. When a dynamic node “evaluates” or is “evaluated,” its charge level corresponds to a valid logic level and may be used or read as such.)

Not every keeper transistor in a chip (or dynamic circuit) may be body biased for a given embodiment. for those that are body biased, a single bias value or multiple bias values may be provided in a chip. For example, in some embodiments, multiple body biases per chip could be used to correct for within-die process variation or within-die temperature variations. As a particular example, dynamic circuits in the execution core of a processor could be connected to one bias value, while dynamic circuits in the cache could be connected to a second unique bias value. Depending on the design of a body bias circuit, different biases for different keeper transistors could be implemented.

A body bias circuit may be any suitable combination of circuit devices that can be programmed with a bias value after a chip has been fabricated and can body bias a transistor such as a keeper transistor with the programmed bias value. The depicted body bias circuit 202 comprises a body bias generator 204 and a bias value file 206. The body bias generator 204 is coupled to the bias value file 206. A bias value programmed in the bias value file 206 after chip fabrication controls the body bias generator 204 to produce a body bias voltage corresponding to this value. The body bias generator 204 is also coupled to the bodies (B) of one or more keeper transistors MKBB in one or more dynamic circuits 201₁ to 201_{N} to bias them at the programmed level. In some embodiments, the bias value corresponds to the amount of leakage in the dynamic circuit(s), some larger block of the chip, or in the chip as a whole. (The amount of leakage in the relevant parts of a dynamic circuit will typically correlate with a leakage associated with the chip or at least with larger, more readily measurable portions of the chip.)

The bias value file stores a bias value that is used to determine the bias voltage generated by body bias generator 204. It could be formed from any suitable circuit device combination to provide sufficient post-fabrication, programmable, non-volatile memory. For example, it could be formed from an array (single or multiple rows) of one time programmable (“OTP”) cells such as fuse cells or other programmable structures.

The body bias generator 204 receives a digital value from the bias value file 206 and converts it to an analog bias voltage that it uses to bias the body of keeper transistor(s) M_{KBB}. A body bias generator 204 may be formed from any suitable combination of circuit devices to generate a desired body bias voltage for its associated one or more keeper transistors to be biased. For example, it could comprise a digital-to-analog (“D/A”) converter with an appropriate output voltage swing. That is, depending upon whether the body bias generator is called on to provide a reverse body bias to its one or more keeper transistors, it may have an output swing extending below ground, above Vcc, or both. For example, with NMOS transistors having their sources coupled to ground, if reverse biasing pursuant to an implemented body biasing scheme is desired, the body bias generator should include a negative output voltage capability. Likewise, with PMOS transistors having their sources coupled to Vcc (as with M_{KBB} in FIG. 2) if reversed biasing is desired, the body bias generator should include an output voltage capability that can exceed Vcc. With either of these cases, as persons of skill will recognize, negative voltages and voltages in excess of Vcc could, for example, be achieved with a D/A converter having one or more appropriately configured charge pump circuits to provide voltages outside of a ground-to-Vcc swing.

In the depicted embodiment, both forward and reverse biasing may be employed. Thus, because keeper transistor M_{KBB} is a PMOS transistor (requiring voltages in excess of V_{CC} for reverse body biasing M_{KBB}) body bias generator 204 may comprise a D/A converter with an above-V_{CC} voltage capability if reverse body biasing is desired.

In some body biasing implementations, after a chip is fabricated, leakage associated with a chip or with a circuit within the chip is determined. (Note that this does not necessarily mean that current leakage is quantified or determined on an absolute basis. When it is stated that leakage is “determined” or “measured,” it is meant that some parameter that at least correlates (or reflects) leakage is determined or measured and either directly or indirectly matched with a suitable keeper transistor strength as desired.) This leakage may be measured either directly or indirectly. that is, while they could be, not every chip (or circuit within a chip) may have to be individually measured and programmed. For example, a set of samples from each lot could be characterized to estimate leakage characteristics associated with other chips in the lot. One or more desired bias values for keeper transistors in chips from the lot could then be determined from this information. In addition, representative leakage for a chip or for a particular area or circuit within a chip could be determined and used for determining bias values.

Based on the determined leakage, the bias value(s) are then determined. In some embodiments, if leakage is low, then keeper transistor strength is also made correspondingly low since its associated dynamic node will be less susceptible to voltage droop. The body bias value would be selected to raise the keeper transistor voltage threshold level (e.g., with a reverse body bias or with a relatively smaller forward body bias). The result is that keeper transistor contention with logic circuit stack(s) is reduced, and the speed of the gate increases. On the other hand, if the leakage of the die is high, the keeper transistor strength would be correspondingly increased since it would supply a larger current to counteract leakage on the dynamic node. The body bias value would thus be selected to lower keeper transistor voltage threshold level (e.g., with a relatively strong forward body bias). In this way, keeper transistors can be “sized” on a per-chip or per-circuit basis to overcome leakage and sufficiently hold charge at the dynamic node when it is to evaluate High and at the same time, be small enough so as not to unreasonably impair discharge and degrade operational performance when the node is to evaluate Low. (It should be appreciated that in some embodiments, the body bias range need not cover both reverse and forward body biasing. For example, in some embodiments, only a forward bias capability may be required. This simplifies the body bias circuit since in most cases, it eliminates the need for a bias voltage that is higher than Vcc or less than ground. In some embodiments using only forward biasing, the keeper transistors target, unbiased threshold levels could be sized so that, with no process variations, a body bias halfway between zero bias and maximum forward bias would be applied for optimal keeper transistor strength (e.g., with a strength that corresponds to actual leakage). That way if the keeper transistor becomes stronger due to process variations, less forward bias could be used, while if the keeper transistor became weaker, more forward bias could be used.

After the one or more bias values for a chip are determined, the bias value file 206 is programmed with this bias value information. Thus, when the chip is operated, one or more of its keeper transistors are body biased so that their effective strengths can better correspond with leakage associated with their particular dynamic circuitry.

With reference to FIG. 3, one example of a system (system 300 for a computer) that may be implemented with one or more IC chips or modules (such as a microprocessor chip 302A) is shown. System 300 generally comprises one or more processor/memory components 302, an interface system 310, and one or more other components 312. At least one of the one or more processor/memory components 302 is communicatively linked to at least one of the one or more other components 312 through the interface system 310, which comprises one or more interconnects and/or interconnect devices including point-to-point connections, shared bus connections, and/or combinations of the same.

A processor/memory component is a component such as a processor, controller, memory array, or combinations of the same contained in a chip or in several chips mounted to the interface system or in a module or circuit board coupled to the interface system. Included within the depicted processor/memory components is microprocessor chip 302A, which has one or more transistors (e.g., keeper transistors) body biased in accordance with an embodiment of the invention, as disclosed herein. The one or more depicted other components 312 could include any component of use in a computer system such as a sound card, network card, Super I/O chip, or the like. In the depicted embodiment, the other components 312 include a wireless interface component 312A, which serves to establish a wireless link between the microprocessor 302A and another device such as a wireless network interface device or a computer. It should be noted that the system 300 could be implemented in different forms. That is, it could be implemented in a single chip module, a circuit board, or a chassis having multiple circuit boards. Similarly, it could constitute one or more complete computers or alternatively, it could constitute a component useful within a computing system.

While the inventive disclosure has been described in terms of several embodiments, those skilled in the art will recognize that the invention is not limited to the embodiments described, but can be practiced with modification and alteration within the spirit and scope of the appended claims. It should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A chip, comprising:
a. a dynamic circuit having a keeper transistor; and
b. a body bias circuit coupled to the keeper transistor, said body bias circuit to body bias the keeper transistor in accordance with a leakage associated with the dynamic circuit.

2. The chip of claim 1, in which the keeper transistor is a PMOS transistor coupled between a supply voltage and a dynamic node of the dynamic circuit.

3. The chip of claim 2, in which the body bias circuit comprises a body bias generator coupled to a body of the keeper transistor.

4. The chip of claim 3, in which the body bias generator is configured to generate a bias voltage in excess of the supply voltage to be capable of reverse body biasing the keeper transistor.

5. The chip of claim 4, in which the body bias generator includes a D/A converter circuit.

6. The chip of claim 5, in which the body bias circuit includes a programmable bias value file to store a bias value to be applied at the keeper transistor.

7. The chip of claim 1, in which the leakage associated with the dynamic circuit is based on a leakage associated with the chip.

8. The chip of claim 7, in which the leakage associated with the chip is determined from measurements of one or more samples from a chip lot that includes the chip.

9. The chip of claim 1, in which the keeper transistor is an NMOS transistor.

10. A chip comprising:
a. a dynamic circuit with a dynamic node; and
b. a transistor coupled to the dynamic node to provide it with charge, said transistor to be body biased at a level corresponding to a leakage associated with the dynamic circuit.

11. The chip of claim 10, in which the transistor is a PMOS transistor coupled between a supply voltage and the dynamic node.

12. The chip of claim 10, further comprising a body bias circuit to body bias the transistor.

13. The chip of claim 12, in which the body bias circuit comprises a body bias generator coupled to a body of the transistor.

14. The chip of claim 13, in which the body bias generator is configured to generate a bias voltage in excess of the supply voltage.

15. The chip of claim 14, in which the body bias generator includes a D/A converter circuit.

16. The chip of claim 15, in which the body bias circuit includes a programmable bias value file to store a bias value to be applied at the transistor.

17. The chip of claim 10, in which the leakage associated with the dynamic circuit is based on a leakage associated with the chip.

18. The chip of claim 17, in which the leakage associated with the chip is determined from measurements of one or more samples from a chip lot that includes the chip.

19. A method comprising:
a. determining a leakage associated with a dynamic circuit of a fabricated chip, the dynamic circuit including a keeper transistor, the chip including (i) the dynamic circuit and (ii) a body bias circuit coupled to the keeper transistor; and
b. programming the body bias circuit to body bias the keeper transistor at a level corresponding to the determined leakage.

20. The method of claim 19, in which the dynamic circuit includes a dynamic logic gate, and the act of determining a leakage comprises determining a leakage associated with the dynamic logic gate.

21. The method of claim 20, in which the act of determining the leakage associated with the dynamic logic gate includes determining a leakage associated with the chip, and determining the leakage associated with the dynamic logic gate based on the leakage associated with the chip.

22. The method of claim 21, in which determining the leakage associated with the chip comprises indirectly determining said leakage based on measurements from other chips in a common chip lot.

23. The method of claim 19, in which the body bias circuit comprises a body bias generator coupled to the keeper transistor and to a bias value file.

24. A system, comprising:
a. a microprocessor comprising:
i. a dynamic circuit with a dynamic node, and
ii. a transistor coupled to the dynamic node to provide it with charge, said transistor to be body biased at a level corresponding to a leakage associated with the dynamic circuit; and
b. a wireless interface component communicatively linked to the microprocessor.

25. The system of claim 24, in which the transistor is a PMOS transistor coupled between a supply voltage and the dynamic node.

26. The system of claim 24, further comprising a body bias circuit to body bias the transistor.

27. The system of claim 25, in which the body bias circuit comprises a body bias generator coupled to a body of the transistor.

28. The system of claim 27, in which the body bias generator is configured to generate a bias voltage in excess of the supply voltage.

29. The system of claim 28, in which the body bias generator includes a D/A converter circuit.

30. The system of claim 29, in which the body bias circuit includes a programmable bias value file to store a bias value to be applied at the transistor.
